(19) United States
(12) Patent Application Publication
(10) Pub. No.: US 2026/0139365 A1
(43) Pub. Date: May 21, 2026

(54) METHOD FOR PRODUCING FILMS CONTAINING AMORPHOUS CARBON, AND PRODUCTS

(71) Applicant: L'Air Liquide, Societe Anonyme pour l'Etude et l'Exploitation des Procedes Georges Claude, Paris (FR)

(72) Inventor: Guillemin Willing, Yokosuka (JP)

(21) Appl. No.: 19/370,015

(22) Filed: Oct. 27, 2025

(30) Foreign Application Priority Data
Nov. 15, 2024 (JP) 2024-199431

(51) Int. Cl. C23C 16/26; C07F 7/12

(52) U.S. Cl. CPC C23C 16/26; C07F 7/12

(57) ABSTRACT

A method for producing an amorphous carbon-containing film which includes a step of forming an amorphous carbon-containing film on a surface of a substrate by contacting the aforementioned substrate with a starting material gas which includes a halogenated carbosilane, at a temperature of ≥300° C. and ≤850° C. in a non-plasma atmosphere.

### CROSS REFERENCE TO RELATED APPLICATIONS

This application claims the benefit of priority under 35 U.S.C. § 119 (a) and (b) to Japanese Patent Application No. 2024-199431, filed Nov. 15, 2024, the entire contents of which are incorporated herein by reference.

### BACKGROUND

### Technical Field

The present invention relates to a method for producing films containing amorphous carbon, and products.

### Background Art

The amorphous carbon-containing films are also called a diamond-like carbon films, and because they have properties such as has heat resistance, high hardness, chemical stability, etching resistance, low friction, optical properties and electrical properties, etc., they are used in various fields such as protective films or sliding films for machinery and tools, moving parts, containers, medical equipment and optical parts, materials for forming electrodes and junctions, and hard mask materials in lithographic processes. The amorphous carbon-containing film is generally formed by a chemical or physical vapor deposition method using a hydrocarbon-containing precursor (U.S. Pat. No. 7,842,622).

### SUMMARY OF THE INVENTION

Most of the conventional forming processes use high-energy plasma or high-temperature processes, due to reaction efficiency. However, there is concern that this may cause problems such as formation of by-products due to plasma or high temperature, and damage to the substrate, and the like. In recent years, side effects caused by plasma and high temperature have become noticeable in precision instruments and detailed machining processes.

The purpose of the present disclosure is to provide a method for producing films containing amorphous carbon without using plasma or high temperature, and products.

As a result of diligent investigations, the inventors discovered that the problem above can be solved by adopting the constitution below.

In one embodiment, the present invention relates to a method for making a film containing amorphous carbon, which includes.
a step of forming an amorphous carbon-containing film on the surface of a substrate by contacting the aforementioned substrate with a starting material gas which includes a halogenated carbosilane, at a temperature of ≥300° C. and ≤850° C. in a non-plasma atmosphere.

In one embodiment, the aforementioned halogenated carbosilane preferably has a halogenated silyl group.

In one embodiment, the aforementioned halogenated carbosilane preferably has a trichlorosilyl group.

In one embodiment, the compositional formula of the aforementioned halogenate carbosilane is preferably represented by Formula (A) below.

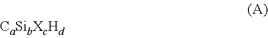

In Formula (A),
   X is a halogen atom (When there is more than one X, the Xs can be the same as or different from each other.);
   a is an integer from 1 to 4;
   b is an integer from 2 to 2a+2;
   c is an integer from 6 to 2a+2b+2;
   d is 2a+2b−c+2.

In one embodiment, the aforementioned halogenated carbosilane is preferably a compound represented by Formula (1) below.

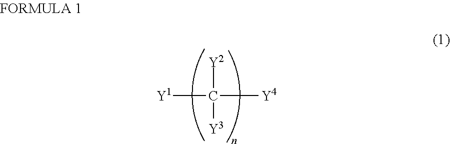

In Formula (1),
   Y¹, Y², Y³ and Y⁴ are each independently a halogenated silyl group, a halogen atom or a hydrogen atom. When there are more than one Y² and Y³, Y² and Y³ can be the same as or different from each other). At least two selected from the group consisting of Y¹, Y², Y³ and Y⁴ are halogenated silyl groups and
   n is an integer of 1 to 4.

In one embodiment, the aforementioned halogenated silyl group is a trichlorosilyl group.

In one embodiment, the aforementioned halogen atoms are preferably chlorine atoms.

In one embodiment, n is preferably 1 or 2.

In one embodiment, the number of hydrogen atoms in the aforementioned halogenated silyl group is ≤2.

In one embodiment, the carbon concentration in the aforementioned amorphous carbon-containing film is preferably ≥85 atom %

In one embodiment, the aforementioned starting material gas preferably includes at least one carrier gas selected from a group consisting of N₂, He, Ar, Kr, Ne and Rn.

In one embodiment, the aforementioned halogenated carbosilane is preferably at least one selected from the group consisting of bis(trichlorosilyl)methane, dichlorobis(trichlorosilyl)methane, difluorobis(trichlorosilyl)methane, tris(trichlorosilyl)methane, 1,2-bis(trichlorosilyl)ethane,1,1-bis(trichlorosilyl)ethane and 1,3-bis(trichlorosilyl)propane.

In a separate embodiment, the present invention relates to a product provided with
a body and
an amorphous carbon-containing film formed on at least a portion of a surface of the aforementioned body by an aforementioned method for producing an amorphous carbon-containing film.

In the present specification, standard abbreviations are used for elements from the periodic table of elements. Accordingly, elements may be represented by these abbreviations. For example, C means carbon, Si means silicon, N means nitrogen, H means hydrogen, He means helium, Ne means neon, Ar means argon, Kr means krypton and Xe means xenon, Rn means radon. The same also applies to other elements.

In the present specification, “CVD” means chemical vapor deposition or chemical evaporation coating and “ALD” means atomic layer deposition. Note that ALD is a type of CVD.

In the present specification, “hydrocarbon group” includes chain hydrocarbon groups, alicyclic hydrocarbon groups and aromatic hydrocarbon groups. This “hydrocarbon group” includes saturated hydrocarbon groups and unsaturated hydrocarbon groups. A “chain hydrocarbon group” means a hydrocarbon group consisting only of a chain structure and not including a ring structure, and includes both straight chain hydrocarbon groups and branched chain hydrocarbon groups. An “alicyclic hydrocarbon group” means a hydrocarbon group in which the ring structure contains only an alicyclic structure and does not contain an aromatic ring structure, including both monocyclic alicyclic hydrocarbon groups and polycyclic alicyclic hydrocarbon groups (note that it does not have to consist only of an alicyclic structure, but can include chain structures in a portion thereof). An “aromatic hydrocarbon group” means a hydrocarbon group in which the ring structures include an aromatic ring structure (however, it does not have to consist only of an aromatic ring structure, but can include chain structures in a portion thereof).

According to the present disclosure, an amorphous carbon-containing film and products provided with the same can be efficiently manufactured without using plasma or high temperature. In addition, according to the present disclosure, it is also possible to design a film forming process at a low temperature (for example, 450° C. or less).

### BRIEF DESCRIPTION OF THE DRAWINGS

For a further understanding of the nature and objects for the present invention, reference should be made to the following detailed description, taken in conjunction with the accompanying drawings, in which like elements are given the same or analogous reference numbers and wherein:

FIG. 1 is results of crystal structure analysis by X-ray diffraction (XRD) of films formed in Examples 1, 8, and 11-13 and the bare Si substrate.

FIG. 2 is graphs showing the atomic structure of the amorphous carbon-containing films formed in Examples 1-2, 8, 11, 12-13 and 15-16.

FIG. 3A is XPS results for the amorphous carbon-containing film formed on an Si substrate by chemical vapor deposition using the halogenated carbosilane in Example 1.

FIG. 3B is XPS results for the amorphous carbon-containing film formed on an Si substrate by chemical vapor deposition using the halogenated carbosilane in Example 2,

FIG. 3C is XPS results for the amorphous carbon-containing film formed on an Si substrate by chemical vapor deposition using the halogenated carbosilane in Example 8.

FIG. 3D is XPS results for the amorphous carbon-containing film formed on an Si substrate by chemical vapor deposition using the halogenated carbosilane in Example 11.

FIG. 3E is XPS results for the amorphous carbon-containing film formed on an Si substrate by chemical vapor deposition using the halogenated carbosilane in Example 12.

FIG. 3F is XPS results for the amorphous carbon-containing film formed on an Si substrate by chemical vapor deposition using the halogenated carbosilane in Example 13

FIG. 3G is XPS results for the amorphous carbon-containing film formed on an Si substrate by chemical vapor deposition using the halogenated carbosilane in Example 15.

FIG. 3H is XPS results for the amorphous carbon-containing film formed on an Si substrate by chemical vapor deposition using the halogenated carbosilane in Example 16.

FIG. 31 is XPS results for the amorphous carbon-containing film formed on an Si substrate by chemical vapor deposition using the halogenated carbosilane in Example 20.

FIG. 4 is a graph showing the temperature dependence of the film thickness of amorphous carbon-containing films.

FIG. 5A is an SEM image of the region from the surface of the trench to a depth of 300 nm in the amorphous carbon-containing film formed on a trench in Example 12.

FIG. 5B is an SEM image of a region near a depth of 3 μm from the surface of the trench in the amorphous carbon-containing film formed on a trench in Example 12.

FIG. 5C is an SEM image of a region near a depth of 6 μm from the surface of the trench in the amorphous carbon-containing film formed on a trench in Example 12.

### DETAILED DESCRIPTION OF THE PREFERRED EMBODIMENTS

Embodiments of the present disclosure are described below, but the present disclosure is not limited in particular to these embodiments, and can be implemented with the addition of suitable alterations. In addition, it can be implemented by combining the different constitutions described below.

### Method for Making an Amorphous Carbon-Containing Film

The method for producing an amorphous carbon-containing film according to the present embodiment includes a step of forming an amorphous carbon-containing film on the surface of a substrate by contacting the aforementioned substrate with a source gas which includes a halogenated carbosilane, at a temperature of ≥300° C. and ≤850° C. in a non-plasma atmosphere (Also referred to hereafter as the “contact step”). This production method can include, as a preparatory step for the contact step, a preliminary condition setting step inside of the reactor in which the substrate is disposed is set to conditions suitable for the contact step. First, the raw material gas including a halogenated carbosilane which is used in the production method will be described, and then each step will be described, based on an embodiment which includes an optional preliminary condition setting step.

### Starting Material Gas

The starting material gas includes a halogenated carbosilane. A halogenated carbosilane is a compound that contains at least carbon atoms, silicon atoms and halogen atoms, and includes an Si—C bond. Up until now, halogenated carbosilanes have mainly been used for forming silicon-containing films. The present inventors discovered that, by changing the viewpoint, a halogenated carbosilane can form an amorphous carbon-containing film by bringing it into contact with a substrate at a certain temperature in a non-plasma atmosphere. The present disclosure is based on this novel insight. The starting material gas can include only a halogenated carbosilane; it can also include other constituents other than halogenated carbosilanes. The starting material gas can include one or two or more halogenated carbosilanes.

Examples of a halogen atom include a fluorine atom, a chlorine atom, a bromine atom, and an iodine atom. Of these, chlorine atoms or fluorine atoms are preferred as halogen atoms, and chlorine atoms are more preferred.

Although there is no particular restriction as to the specific structure of the halogenated carbosilane, the aforementioned halogenated carbosilane preferably has a halogenated silyl group. A halogenated silyl group is a group which has a silyl group (—SiH₃) in which some or all of the hydrogen atoms are replaced by halogen atoms, Therefore, examples of halogenated silyl groups include monohalosilyl groups, dihalosilyl groups and trihalosilyl groups. As the halogenated silyl group a trihalosilyl group is preferred, and a trichlorosilyl group is more preferred.

As the structure of the halogenated carbosilane, a structure in which some or all of the hydrogen atoms of the hydrocarbon are replaced by halogenated silyl groups is preferred. Examples of hydrocarbons include C1-10 chain hydrocarbons, C3-10 alicyclic hydrocarbons and C6-10 aromatic hydrocarbons, and combinations thereof.

Examples of C1-10 chain hydrocarbons include straight-chain or branched alkanes such as methane, ethane, propane, 2-methylpropane, 2, 2-dimethylpropane, n-butane, 2-methylbutane and n-pentane, alkenes such as ethylene, propene, 1-butene and 2-butene, and alkynes such as acetylene, propyne; 1-butyne and 2-butyne, and the like.

Examples of monovalent alicyclic hydrocarbons having 3 to 10 carbons include monocyclic saturated alicyclic hydrocarbons such as cyclopentane, cyclobutane and cyclohexane, polycyclic saturated alicyclic hydrocarbons such as norbornane, adamantane and tricyclodecane, monocyclic unsaturated alicyclic hydrocarbons such as cyclopentene, cyclobutene, cyclopentene and cyclohexene, and polycyclic unsaturated alicyclic hydrocarbons such as norbornene and tricyclodecene and the like.

Examples of monovalent aromatic hydrocarbons having 6-12 carbons include allenes such as benzene and naphthalene and the like.

As the aforementioned hydrocarbon a C1-10 chain hydrocarbon is preferred, a C1-8 saturated chain hydrocarbon is more preferred, a C1-6 saturated straight-chain hydrocarbon is even more preferred and a C1-4 straight-chain saturated hydrocarbon is particularly preferred.

The compositional formula of the aforementioned halogenated carbosilane is preferably represented by Formula (A) below.

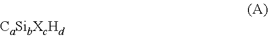

In Formula (A),
   X is a halogen atom. (When there is more than one X, the Xs can be the same as or different from each other.);
   a is an integer from 1 to 4;
   b is an integer from 2 to 2a+2;
   c is an integer from 6 to 2a+2b+2; and
   d is 2a+2b−c+2.

As the halogen atom represented by X, an aforementioned halogen atom can favourably be adopted.
a is preferably an integer from 1 to 3; it is more preferably 1 or 2, and is even more preferably 1;
b is preferably an integer from 2 to 4, and is more preferably 2 or 3;
c is preferably integer from 6 to 10, and more preferably an integer from 6 to 9;and
d is preferably an integer from 0 to 4, more preferably an integer from 0 to 2, and more preferably 0 or 1.

In particular, as the structure of the halogenated carbosilane, the aforementioned hydrocarbons and aforementioned halogenated silyl groups are preferably combined so as to satisfy the compositional formula represented by the aforementioned formula (A); more preferably aforementioned C1-6 saturated linear hydrocarbons are combined with aforementioned trihalosilyl groups, and even more preferably aforementioned C1-4 saturated linear hydrocarbons are combined with trichlorosilyl groups.

The aforementioned halogenated carbosilane is preferably a compound represented by Formula (I) below.

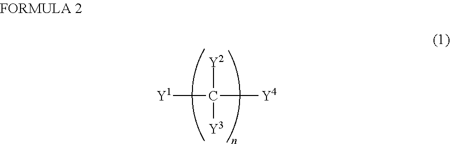

In Formula (1),
   Y¹, Y², Y³ and Y⁴ are each independently a halogenated silyl group, a halogen atom or a hydrogen atom. When there are more than one Y² and Y³, the more than one Y² and Y³ can be the same as or different from each other. At least two selected from the group consisting of Y¹, Y², Y³ and Y⁴ are halogenated silyl groupsand n is an integer of 1 to 4.

As halogenated silyl groups and halogen atoms represented by Y¹, Y², Y³ and Y⁴ the halogenated silyl groups and halogen atoms described above can be favourably adopted.
n is preferably an integer 1-3, more preferably it is 1 or 2, and even more preferably it is 1.

The number of halogenated silyl groups in Y¹, Y², Y³ and Y⁴ is preferably from 2 to 4, and more preferably it is 2 or 3.

The number of hydrogen atoms in the aforementioned halogenated carbosilane is preferably ≤2; more preferably it is 0 or 1, and more preferably it is 0.

As aforementioned halogenated carbosilanes, for example, bis(trichlorosilyl) methane (the compound represented by Formula (1-1) below), dichlorobis(trichlorosilyl)methane (the compound represented by Formula (1-2) below), difluorobis(trichlorosilyl)methane (compound represented by Formula (1-3) below), tris(trichlorosilyl)methane (compound represented by Formula (1-4) below), 1,2-bis(trichlorosilyl)ethane (compound represented by Formula (1-5) below), 1,1-bis(trichlorosilyl)ethane (compound represented by Formula (1-6) below), chlorotris(trichlorosilyl)methane (compound represented by Formula (1-7) below), chlorobis(trichlorosilyl)methane (compound represented by Formula (1-8) below), 1,2-dichloro-1,2-bis(trichlorosilyl)ethane (compound represented by Formula (1-9) below), tetra(trichlorosilyl)methane (compound represented by Formula (1-10) below), 1,3-bis(trichlorosilyl)propane (compound represented by Formula (1-11) below), 1,1,1,3,3,3-hexachloro-2,2-dimethyl-1,3-dislapropane (compound represented by Formula (1-12) below), 1,1,1,3,3,3-hexachloro-2-ethyl-1,3-disilapropane (compound represented by Formula (1-13) below), and 1,1,1,4,4,4-hexachloro-2-methyl-1,4-disilabutane (compound represented by Formula (1-14) below), etc. can be cited.

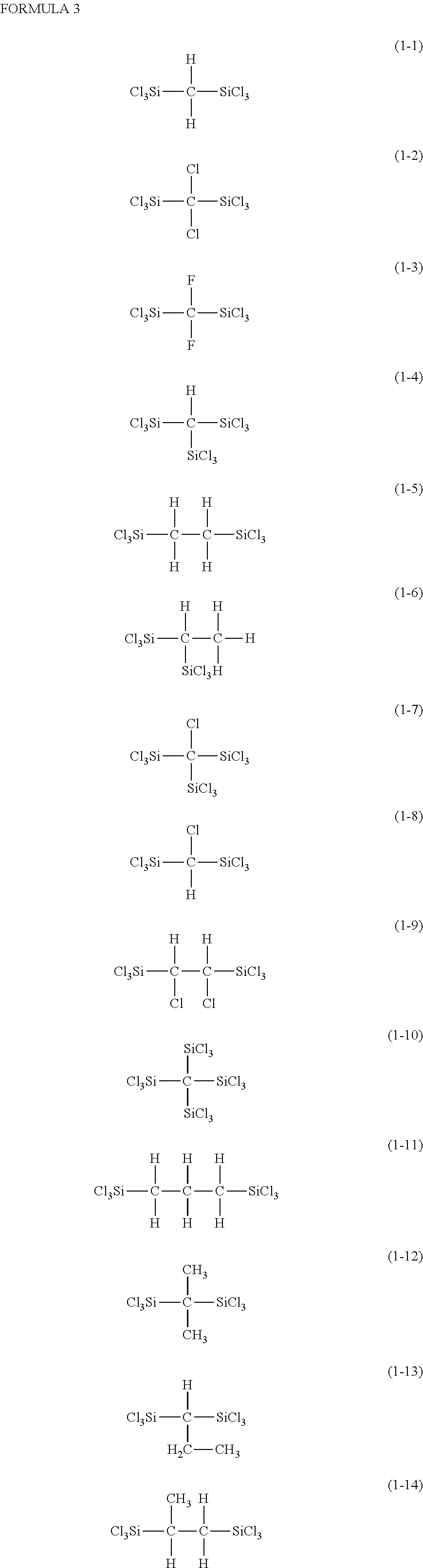

The aforementioned halogenated carbosilane is preferably at least one selected from a group consisting of bis(trichlorosilyl)methane (compound represented by aforementioned Formula (1-1)), dichlorobis(trichlorosilyl)methane (compound represented by aforementioned Formula (1-2)), difluorobis(trichlorosilyl)methane (compound represented by aforementioned Formula (1-3)), tris(trichlorosilyl)methane (compound represented by aforementioned Formula (1-4)), 1,2-bis(trichlorosilyl)ethane (compound represented by aforementioned Formula (1-5)), 1,1-bis(trichlorosilyl)ethane (compound represented by aforementioned Formula (1-6)) and 1,3-bis(trichlorosilyl)propane (compound represented by aforementioned Formula (1-11)).

### Method for Synthesizing the Halogenated Carbosilane

The halogenated carbosilane can be synthesized by a known method. Commercially available halogenated carbosilanes can also be used.

### Preliminary Condition Setting Step

In this step, the reactor in which the substrate has been disposed is set to conditions suitable for the contact step. The type of substrate on which the amorphous carbon-containing film is deposited is to be selected as appropriate, in accordance with the end use.

In some embodiments, the substrate can be selected from Si substrates and oxides used as insulating materials in MIM, DRAM, or FeRAM technologies (for example, HfO₂ based materials, TiO₂ based materials, ZrO₂ based materials, rare earth oxide-based materials, ternary oxide-based materials, and the like) or from nitride-based films used as an oxygen barrier between copper and low-k films (e.g. TaN). In the production of semiconductors, photovoltaic cells, LCD-TFTs, or flat panel devices, other substrates can be used. Examples of such substrates include, but are not limited to, other substrates, including any solid substrate such as metal-nitride-containing substrates (for example, TaN, TiN, WN, TaCN, TiCN, TaSiN, and TiSiN), insulators (for example, SiO₂, Si₃N₄, SiON, HfO₂, Ta₂O₅, ZrO₂, TiO₂, Al₂O₃, and barium strontium titanate); or combinations of these materials. The substrate actually used also depends on the specific embodiment of the starting material gas that is employed.

The reactor can be any closed container or chamber in a device in which a vapor deposition method is carried out. Examples include, but are not limited to, parallel plate type reactors, cold wall type reactors, hot wall type reactors, single plate reactors, multi-wafer reactors, or other types of deposition systems.

The substrate can be heated to a sufficient temperature to obtain the desired amorphous carbon-containing film at a sufficient growth rate and with the desired physical state and composition. The temperature inside the reactor (substrate surface temperature) should be set in the range ≥300° C. and ≥850° C. The aforementioned temperature is preferably in the range ≥300° C. and ≤750° C., more preferably ≥350° C. and ≤700° C. and even more preferably ≥350° C. and ≤650° C.

The temperature inside the reactor (substrate surface temperature) can be set in accordance with the type of halogenated carbosilane. When the halogenated carbosilane is bis(trichlorosilyl)methane, 1,2-bis(trichlorosilyl)ethane, 1,1-bis(trichlorosilyl)ethane or 1,3-bis(trichlorosilyl)propane, the aforementioned temperature is preferably ≥800° C. and ≤850° C. When the halogenated carbosilane is tris(trichlorosilyl)methane, the aforementioned temperature is preferably ≥500° C. and ≤600° C. When the halogenated carbosilane is dichlorobis(trichlorosilyl)methane, the aforementioned temperature is preferably ≥450° C. and ≤500° C.

While heating the substrate, an inert gas can be introduced into the reactor in order to stabilize the pressure inside the reactor. Inert gasses include, but are not limited to, at least one selected from the group consisting of N₂, He, Ar, Kr, Xe, Ne and Rn.

The flow rate of the inert gas can be set as appropriate; it is preferably 1-100 sccm, and 10-50 sccm is more preferred.

The halogenated carbosilane can be provided in a pure form (for example as a liquid or a low melting point solid).

### Contact Step

In this step, the starting material gas containing a halogenated carbosilane which is introduced into the reactor in the introduction step and the substrate are brought into contact at a temperature of ≥300° C. and ≥850° C. under a non-plasma atmosphere and an amorphous carbon-containing film is formed on the surface of the aforementioned substrate. The substrate temperature in the aforementioned preliminary condition setting step is maintained in this step.

By introducing a starting material gas which includes vaporized halogenated carbosilane into the aforementioned reactor, the starting material and the substrate can be brought into contact. A pure (single) halogenated carbosilane or a blend of (multiple) halogenated carbosilanes can be supplied in liquid form to a vaporizer, and vaporized thereby before being introduced into the reactor. Alternatively, the halogenated carbosilane can be vaporized by passing a carrier gas through a container containing the halogenated carbosilane, or by bubbling a carrier gas into the halogenated carbosilane.

In the contact step, an amorphous carbon-containing film can be formed simply by introducing a starting material gas which includes a halogenated carbosilane, without separate introduction of an oxidizing gas (oxygen gas or water, etc.) or a catalyst gas (amine, etc.), or the like.

The pressure inside the reactor is preferably in the range 0.01 Torr to 50 Torr, more preferably within the range 0.1 Torr to 20 Torr is more preferable, and even more preferably within the range 0.5 Torr to 10 Torr.

In this step, the intended amorphous carbon-containing film can be formed simply by bringing a starting material gas containing a halogenated carbosilane and a substrate into contact within a certain temperature range, without having the plasma atmosphere frequently used in prior methods. In this process, the halogenated carbosilane undergoes thermal decomposition, and an amorphous carbon-containing film is formed by deposition of carbon onto the substrate. Because there is a non-plasma atmosphere, production of by-products and damage to the substrate during the deposition process can be kept to a minimum.

The thickness of the amorphous carbon-containing film obtained from the present production method can be set as appropriate for the intended use. The lower limit of the film thickness of the amorphous carbon-containing film can be 1 nm, can be 5 nm, can be 10 nm, or can be 15 nm. The upper limit of the aforementioned thickness can be 5 μm, can be 3 μm, can be 1 μm or can be 500 nm.

The carbon concentration in the amorphous carbon-containing film obtained from the present production method is preferably 85 atom %. The lower limit of the aforementioned carbon concentration is more preferably 86 atom %, even more preferably 87 atom %, and particularly preferably 88 atom %. Although the upper limit of the aforementioned carbon concentration is preferably as high as possible, it can be 99.5 atom %, or can be 99 atom %. By using a halogenated carbosilane it is possible to form an amorphous carbon-containing film having a high carbon concentration even in a non-plasma atmosphere by simply contacting the substrate at a certain temperature.

The amorphous carbon-containing film can contain chlorine, oxygen, nitrogen, silicon, or the like in addition to carbon. Chlorine concentration is preferably ≤5 atom %, and ≤4 atom % is more preferred. Oxygen concentration is preferably ≤5 atom %, and ≤4 atom % is more preferred. The nitrogen concentration is preferably ≤2 atom %, and ≤1 atom % is more preferred. The silicon concentration is preferably ≤6 atom %, ≤5 atom % is more preferred, ≤4 atom % is even more preferred, and ≤3 atom % is particularly preferred. The lower limits of the concentrations of chlorine, oxygen, nitrogen and silicon are preferably as low as possible. In all cases, the lower limit of the concentration can be 0.1 atom %, can be 0.2 atom %, or can be 0.3 atom %.

There is no particular restriction as to the applications of amorphous carbon-containing films formed by the production method in question, and they can be employed in various applications such as, for example, in hard mask layers for patterning applications in producing semiconductor devices, in forming electrodes and contact formation, in thin film deposition for micro electromechanical systems (MEMS), in substrates for growing carbon nanotubes and graphene, and in low-friction coatings for moving parts of electronic devices, and the like.

### EXAMPLES

Examples are described below in order to illustrate the application of the disclosure in this specification; however it should be fully understood that all of the advantages of the process described in this specification cannot be encompassed in a specific embodiment or group of embodiments of the present invention. Although particular embodiments and examples are disclosed below, it should be understood that the present invention may be extended beyond the specifically disclosed embodiments and/or uses of the present invention, including obvious modifications made by those skilled in the art. Therefore, it should be understood that the scope of the disclosed invention should not be limited by the specific embodiments described below.

### Halogenated Carbosilane

As the halogenated carbosilane for forming amorphous carbon-containing films, compounds represented by the formulae below were used. The halogenated carbosilanes are represented below by abbreviations.
BTCSM: Bis(trichlorosilyl)methane
1,2-BTCSE: 1,2-bis(trichlorosilyl)ethane
1,1-BTCSE: 1,1-bis(trichlorosilyl)ethane
1,3-BTCSP: 1,3-bis(trichlorosilyl)propane,
DCBTCSM: Dichlorobis(trichlorosilyl)methane
TTCSM- Tris(trichlorosilyl)methans

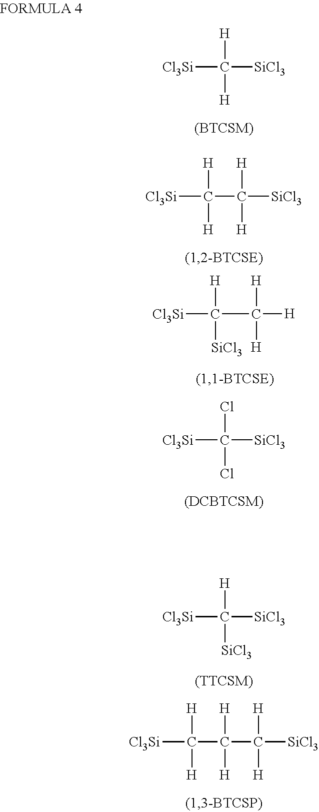

Formation of Amorphous Carbon-Containing Films

### Example 1

An amorphous carbon-containing film was formed on a silicon wafer as a substrate, using BTCSM as the halogenated carbosilane. Specifically, a Si substrate cleaned with a 1 vol % HF solution was mounted inside a fluidized reactor. An amorphous carbon-containing film of film thickness 8 nm was produced by mixing BTCSM with an N₂ carrier gas (N₂ flow 35 sccm and BTCSM flow 2 sccm), and gas phase deposition for 60 minutes at 5 Torr with substrate surface temperature 800° C.

### Example 2

An amorphous carbon-containing film having a film thickness of 23 nm was formed by the same method as in Example 1, except that the gas phase deposition time was set to 120 minutes.

### Example 3

An amorphous carbon-containing film having a film thickness of 1.7 nm was formed by the same method as in Example 1, except that the substrate surface temperature was 700° C.

### Example 4

An amorphous carbon-containing film having a film thickness of 0.9 nm was formed by the same method as in Example 1, except that the substrate surface temperature was 600° C.

### Example 5

An amorphous carbon-containing film having a film thickness of 1.1 nm was formed by the same method as in Example 1, except that 1,2-BTCSE was used as the halogenated carbosilane and the substrate surface temperature was 600° C.

### Example 6

An amorphous carbon-containing film having a film thickness of 1.4 nm was formed by the same method as in Example 1, except that 1,2-BTCSE was used as the halogenated carbosilane and the substrate surface temperature was 700° C.

### Example 7

An amorphous carbon-containing film having a film thickness of 5.2 nm was formed by the same method as in Example 1, except that 1,2-BTCSE was used as the halogenated carbosilane and the substrate surface temperature was 800° C.

### Example 8

An amorphous carbon-containing film having a film thickness of 14.1 nm was formed by the same method as in Example 1, except that 1,2-BTCSE was used as the halogenated carbosilane and the substrate surface temperature was 850° C.

### Example 9

An amorphous carbon-containing film having a film thickness of 0.9 nm was formed by the same method as in Example 1, except that 1,1-BTCSE was used as the halogenated carbosilane and the substrate surface temperature was 700° C.

### Example 10

An amorphous carbon-containing film having a film thickness of 1.1 nm was formed by the same method as in Example 1, except that 1,1-BTCSE was used as the halogenated carbosilane and the substrate surface temperature was 800° C.

### Example 11

An amorphous carbon-containing film having a film thickness of 14.3 nm was formed by the same method as in Example 1, except that 1,1-BTCSE was used as the halogenated carbosilane and the substrate surface temperature was 850° C.

### Example 12

An amorphous carbon-containing film having a film thickness of 14.7 nm was formed by the same method as in Example 1, except that DCBTCSM was used as the halogenated carbosilane and the substrate surface temperature was 450° C.

### Example 13

An amorphous carbon-containing film having a film thickness of 47 nm was formed by the same method as in Example 12, except that the substrate surface temperature was 500° C.

### Example 14

An amorphous carbon-containing film having a film thickness of 3.5 nm was formed by the same method as in Example 12, except that the substrate surface temperature was 400° C.

### Example 15

An amorphous carbon-containing film having a film thickness of 3.7 nm was formed by the same method as in Example 1, except that TTCSM was used as the halogenated carbosilane and the substrate surface temperature was 500° C.

### Example 16

An amorphous carbon-containing film having a film thickness of 50.2 nm was formed by the same method as in Example 15, except that the substrate surface temperature was 600° C.

### Example 17

An amorphous carbon-containing film having a film thickness of 1.1 nm was formed by the same method as in Example 15, except that the substrate surface temperature was 300° C.

### Example 18

An amorphous carbon-containing film having a film thickness of 3.1 nm was formed by the same method as in Example 1, except that 1,3-BTCSP was used as the halogenated carbosilane and the substrate surface temperature was 750° C.

### Example 19

An amorphous carbon-containing film having a film thickness of 7.5 nm was formed by the same method as in Example 18, except that the substrate surface temperature was 800° C.

### Example 20

An amorphous carbon-containing film having a film thickness of 13.6 nm was formed by the same method as in Example 18, except that the substrate surface temperature was 850° C.

### Evaluation

Confirmation of being an Amorphous Film

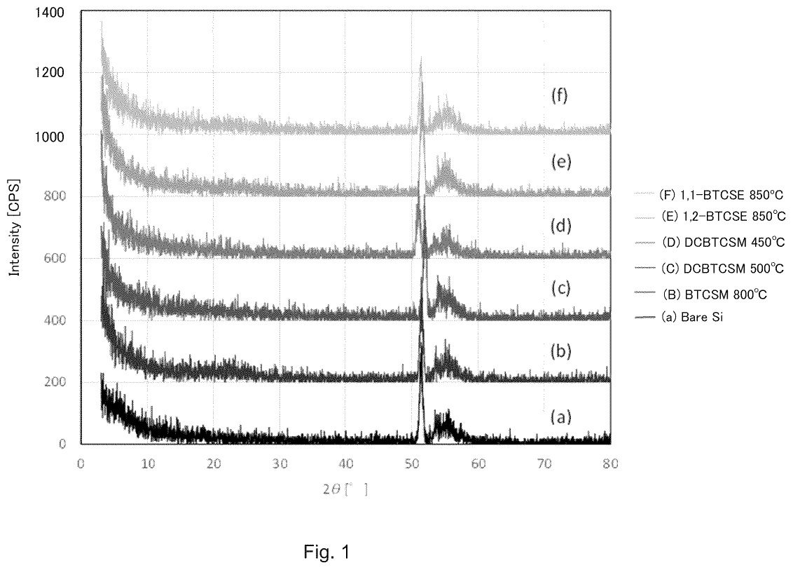

The crystal structures of the films formed in Examples 1, 8, and 11-13 and the bare Si substrates were evaluated by X-ray diffraction (XRD). Specifically, they were measured using an X-ray diffractometer (“SmartLab”, produced by Rigaku Corp.), with 2θ scan: 3-80°, steps: 0.02°, speed: 10°/minute, and receiving slit 0.1 mm. The results are shown in FIG. 1. In films having a crystalline structure, specific peaks are observed because the constituent atoms are regularly arranged. In each measurement sample, a peak similar to that of a bare Si substrate was observed in 2θ between 50° and 60°, but no other characteristic peak was observed. Given this, the films formed in Examples 1, 8, and 11-13 were recognized to be amorphous films.

### Atomic Composition

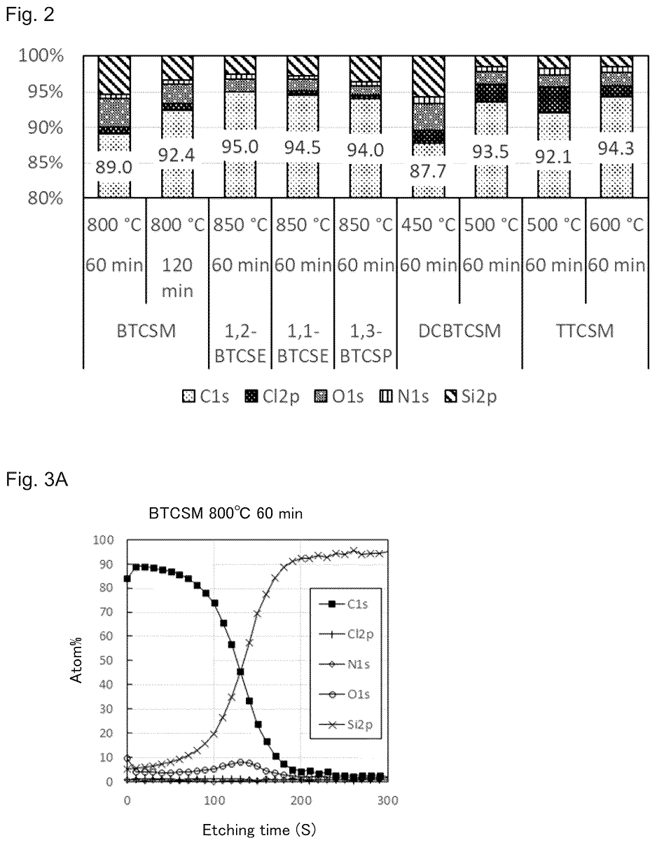

The atomic composition of the amorphous carbon-containing films formed in Examples 1 to 2, 8, 11, 12-13, 15-16 and 20 was measured using an X-ray photoelectron spectrometer (manufactured by Thermo Fisher Scientific, trade name: “K-Alpha”). The results are shown in FIG. 2. FIG. 2 is graphs showing the atomic composition of the amorphous carbon-containing films formed in Examples 1-2, 8, 11, 12-13, 15-16 and 20. From FIG. 2, in each of the amorphous carbon-containing films the carbon concentration showed a high value, exceeding 85 atom %.

### Depth Profile by XPS

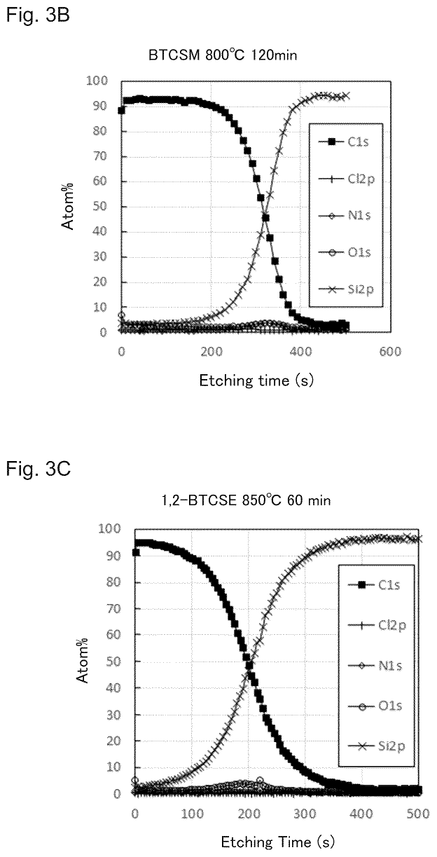

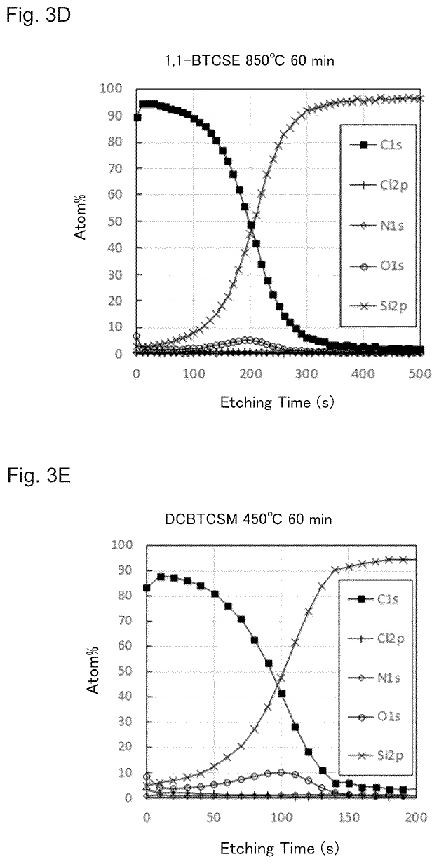

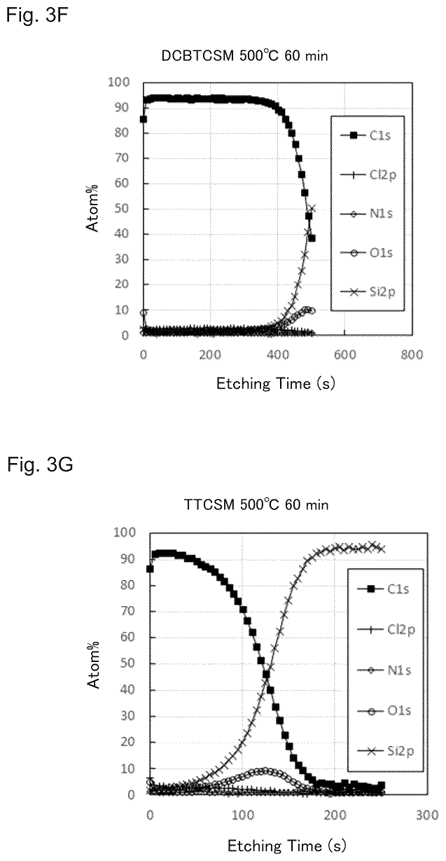

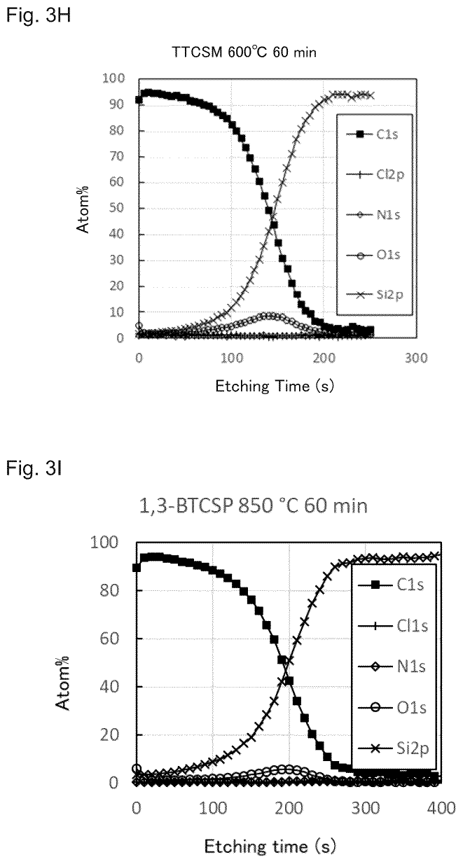

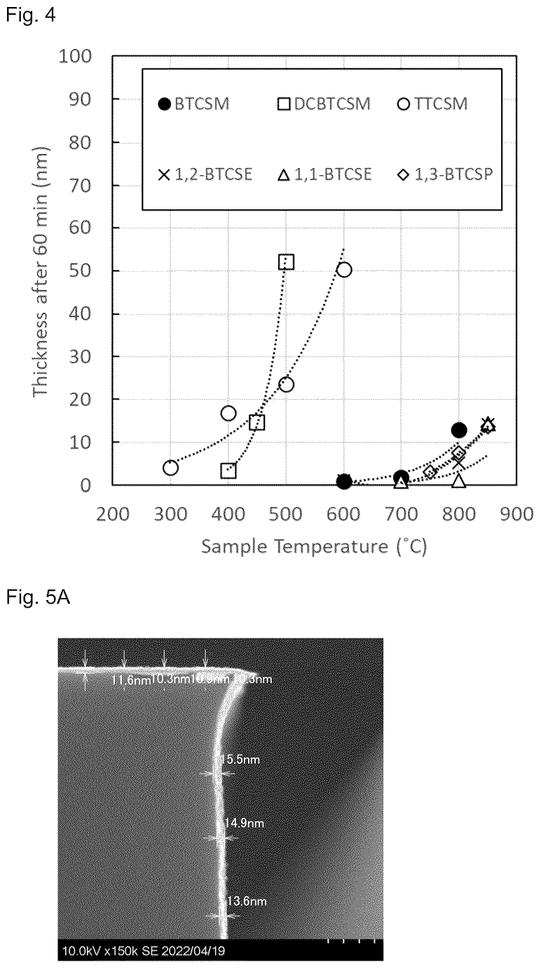

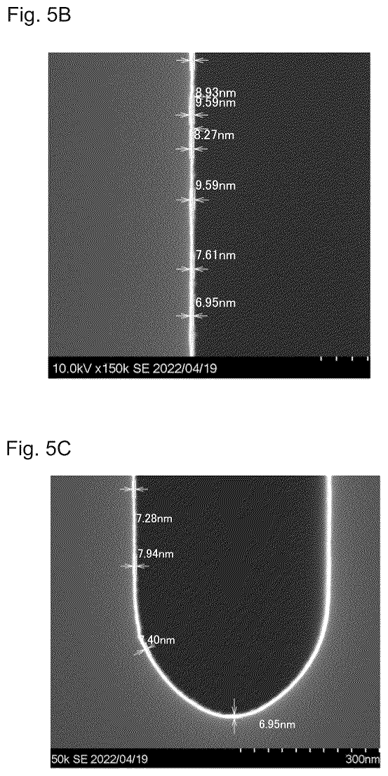

The depth profiles of the amorphous carbon-containing films formed in Examples 1-2, 8, 11-13,15-16 and 20 were evaluated using X-ray photoelectron spectrophotometer (XPS) (trade name: “K-Alpha”, manufactured by Thermo Fisher Scientific). FIG. 3A to FIG. 31 are the XPS results for amorphous carbon-containing films formed on a Si substrate by chemical vapor deposition using the halogenated carbosilanes in Examples 1-2, 8, 11-13 and 15-16 and 20 respectively. From FIG. 3A to FIG. 31, it can be emphasized that a uniform composition was obtained in the amorphous carbon-containing films.

### Temperature Dependence of the Film Thickness of Amorphous Carbon-Containing Films

Changes in the film thickness when amorphous carbon-containing films were formed by gas phase deposition at different temperatures for the same duration using the aforementioned three halogenated carbosilanes in Examples 1 and 3-20 were evaluated. FIG. 4 is graphs showing the temperature-dependence of the film thickness of the amorphous carbon-containing films when vapor phase deposition is carried out at different temperature for the same duration, the film thickness tends to increase as the temperature rises.

### Four-Point Probe Resistance Measurement

On the amorphous carbon-containing films formed in Example 2 and Example 13, the resistance value was measured using a 4-point probe resistance measurement device (product name of “2400 SMU” manufactured by Keithley Co., Ltd.). The results are shown in Table 1 below. It was evident that specimens made at low temperature using DCBTCSM have lower resistivity than specimens made at high temperature using BTCSM.

TABLE 1

| | Substrate | Film | Sheet | |
|---|---|---|---|---|
| | temperature | thickness | resistance | Resistance |
| | (° C.) | (nm) | (Ω/sq) | (μΩ · cm) |
| Example 2 | 800 | 23 | 165 | 1720 |
| BTCSM | | | | |
| Example 13 | 500 | 47 | 30 | 640 |
| DCBCTSM | | | | |

### SEM Imaging of the Amorphous Carbon-Containing Films

By the same procedure as in Example 12 (DCBTCSM), an amorphous carbon-containing film was formed in a trench (CD: 300 nm; depth: 6 μm; aspect ratio: 20:1) formed in the surface of an Si substrate. The cross-section of the trench was observed in the direction perpendicular to the direction of trench formation with a scanning electron microscope (SEM) (trade name: “SU9000”, manufactured by Hitachi, Ltd.) in a region from the surface of the trench to a depth of 300 nm, a region around a depth of 3 μm, and an area around a depth of 6 μm (magnification: ×150,000). FIG. 5A is an SEM image of the region from the surface of a trench to a depth of 300 nm, FIG. 5B is an SEM image of the region around 3 μm from the surface of a trench, and FIG. 5C is an SEM image of the region around a depth of 6 μm from the surface of the trench. The film thickness of the amorphous carbon-containing film was measured at least 3 arbitrary points in each region and the average values thereof were calculated. It should be noted that in the photos there are positions in which the film thickness measurement position (positions shown by two arrows) and the measured values are not aligned. Since the order of measurement points and the order of measured values are consistent, the values can be read based on this relationship. For example, there are four measurement locations in the upper part of the drawing of FIG. 5A. The corresponding measured values, from the left, are 11.6 nm, 10.3 nm, 10.9 nm and 10.3 nm. And the average film thicknesses and the step coverage in each region are shown in Table 2 below.

TABLE 2

| | | Depth | Depth | Depth |
|---|---|---|---|---|
| | Surface | 300 nm | 3 μm | 6 μm |
| Average film thickness (nm) | 10.8 ± 1 | 14.7 ± 1 | 8.5 ± 1 | 7.4 ± 1 |
| Step coverage (%) | 74 | 100 | 58 | 50 |

From FIGS. 5A to 5C and Table 2 it is evident that even in the trench a conformal amorphous carbon-containing film with a significant film thickness was formed by DCBTCSM.

It will be understood that many additional changes in the details, materials, steps and arrangement of parts, which have been herein described in order to explain the nature of the invention, may be made by those skilled in the art within the principle and scope of the invention as expressed in the appended claims. Thus, the present invention is not intended to be limited to the specific embodiments in the examples given above and/or the attached drawings.

While embodiments of this invention have been shown and described, modifications thereof may be made by one skilled in the art without departing from the spirit or teaching of this invention. The embodiments described herein are exemplary only and not limiting. Many variations and modifications of the composition and method are possible and within the scope of the invention. Accordingly, the scope of protection is not limited to the embodiments described herein, but is only limited by the claims which follow, the scope of which shall include all equivalents of the subject matter of the claims.

What is claimed is:

1. A method for producing an amorphous carbon-containing film comprising a step of:
forming an amorphous carbon-containing film on the surface of a substrate by contacting the aforementioned substrate with a starting material gas which includes a halogenated carbosilane, at a temperature of ≥300° C. and ≥850° C. in a non-plasma atmosphere.

2. The method of claim 1, wherein the aforementioned halogenated carbosilane has a halogenated silyl group.

3. The method of claim 1, wherein the aforementioned halogenated carbosilane has a trichlorosilyl group.

4. The method of claim 1, wherein the compositional formula of the aforementioned halogenated carbosilane is represented by Formula (A) below 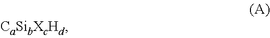
wherein
X is a halogen atom, provided that when there are more than one X, the more than one X are the same as or different from each other);
a is an integer from 1 to 4;
b is an integer from 2 to 2a+2;
c is an integer from 6 to 2a+2b+2; and
d is 2a+2b−c+2.

5. The method of claim 1, wherein the aforementioned halogenated carbosilane is a compound represented by Formula (1) below 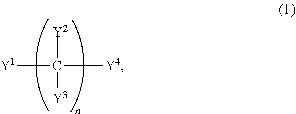
wherein Y¹, Y², Y³ and Y⁴ are each independently a halogenated silyl group, a halogen atom or a hydrogen atom, provided that when there are more than one Y² and Y³, the more than one Y² and Y³ are the same as or different from each other), at least two selected from the group consisting of Y¹, Y², Y³ and Y⁴ are halogenated silyl groups; n is an integer from 1 to 4.

6. The method of claim 1, wherein an aforementioned halogenated silyl group is a trichlorosilyl group.

7. The method of claim 1, wherein an aforementioned halogen atom is a chlorine atom.

8. The method of claim 5, wherein n is 1 or 2.

9. The method of claim 1, wherein the number of hydrogen atoms in the halogenated carbosilane is two or less.

10. The method of claim 1, wherein the carbon concentration in the aforementioned amorphous carbon-containing film is at least 85 atom %.

11. The method of claim 1, wherein the aforementioned starting material gas includes at least one carrier gas selected from a group consisting of N₂, He, Ar, Kr, Ne and Rn.

12. The method of claim 1, wherein the aforementioned halogenated carbosilane is at least one selected from a group consisting of bis(trichlorosilyl)methane, dichlorobis(trichlorosilyl)methane, difluorobis(trichlorosilyl)methane, tris(trichlorosilyl)methane, 1,2-bis(trichlorosilyl)ethane, 1,1-bis(trichlorosilyl)ethane and 1,3-bis(trichlorosilyl)propane.
